(19) United States
(12) Patent Application Publication
(10) Pub. No.: US 2026/0255765 A1
(43) Pub. Date: Aug. 27, 2026

(54) LIGHT-EMITTING DEVICE AND DISPLAY APPARATUS INCLUDING THE SAME

(71) Applicant: SAMSUNG ELECTRONICS CO., LTD., Suwon-si (KR)

(72) Inventors: Suyeon LEE, Suwon-si (KR); Sookyoung Roh, Suwon-si (KR); Sangyun Lee, Suwon-si (KR); Sungmo Ahn, Suwon-si (KR); Kyungwook Hwang, Suwon-si (KR)

(73) Assignee: SAMSUNG ELECTRONICS CO., LTD., Suwon-si (KR)

(21) Appl. No.: 19/377,813

(22) Filed: Nov. 3, 2025

(30) Foreign Application Priority Data
Feb. 25, 2025 (KR) 10-2025-0024587

(51) Int. Cl. H10H 29/855; H10H 29/01; H10H 29/14; H10H 29/80

(52) U.S. Cl. CPC H10H 29/855; H10H 29/0363; H10H 29/14; H10H 29/842; H10H 29/8421

(57) ABSTRACT

A light-emitting device may include a vertical stack structure including first to third epitaxial structures that are sequentially stacked, a separation layer on the third epitaxial structure, a plurality of nanostructures on the separation layer, and a background medium between the plurality of nanostructures, wherein each of the plurality of nanostructures may include a first layer and a second layer on the first layer.

### CROSS-REFERENCE TO RELATED APPLICATION

This application is based on and claims priority under 35 U.S.C. §119 to Korean Patent Application No. 10-2025-0024587, filed on February 25, 2025, in the Korean Intellectual Property Office, the disclosure of which is incorporated by reference herein in its entirety.

### BACKGROUND

### FIELD

The disclosure relates to a light-emitting device and a display apparatus including the light-emitting device.

### DESCRIPTION OF RELATED ART

Light-emitting devices (LEDs) such as light-emitting diodes have characteristics such as long lifespan, low power consumption, high response speed, and environmental friendliness. Owing to these characteristics, industrial demand for LEDs is increasing, and techniques for manufacturing high-resolution display apparatuses using micro-LEDs have recently been attracting attention.

Enhancing light extraction efficiency in a vertical direction is required to improve the performance of micro-LEDs. To this end, a technique of using a microlens structure to narrow the emission angle of light and thus to increase vertical light extraction may be used. However, as the resolution of displays increases, the interval between micro-LEDs decreases, limiting the size of microlens structures that may be integrated. Therefore, a new optical structure is required to improve vertical light extraction without being restricted by size limitations.

### SUMMARY

Provided are a light-emitting device having a vertical stack structure and a display apparatus including the light-emitting device.

Additional aspects will be set forth in part in the description which follows and, in part, will be apparent from the description, or may be learned by practice of the presented embodiments of the disclosure.

According to an aspect of the disclosure, a light-emitting device may include: a vertical stack structure including a first epitaxial structure, a second epitaxial structure on the first epitaxial structure in a first direction, and a third epitaxial structure on the second epitaxial structure in the first direction; a separation layer on the third epitaxial structure in the first direction; a plurality of nanostructures on the separation layer in the first direction; and a background medium between the plurality of nanostructures, wherein each of the plurality of nanostructures includes a first layer and a second layer on the first layer in the first direction.

In each of the plurality of nanostructures, a center of the second layer is overlapping in the first direction with a center of the first layer.

A center, in a second direction crossing the first direction, of the second layer of a nanostructure from among the plurality of nanostructures may be spaced from a center, in the second direction, of the first layer of the nanostructure.

The plurality of nanostructures may include: a first nanostructure, wherein a center, in a second direction crossing the first direction, of the first layer of the first nanostructure is at a first distance from a center, in the second direction, of the first layer of the first nanostructure; and a second nanostructure that is closer than the first nanostructure to a center of the light-emitting device in the second direction, wherein a center, in the second direction, of the first layer of the second nanostructure is at a second distance from a center, in the second direction, of the first layer of the second nanostructure, and the second distance is smaller than the first distance.

A width, in a second direction crossing the first direction, of the second layer of one of the plurality of nanostructures may be different from a width, in the second direction, of the second layer of another one of the plurality of nanostructures.

A refractive index of a of the plurality of nanostructures may be greater than a refractive index of a material of the background medium.

The plurality of nanostructures may be arranged at a pitch of 500 nm to 800 nm.

The first layer may gave a width, in a second direction crossing the first direction, of 300 nm to 600 nm.

The first layer may have a height of 400 nm or less.

The second layer may have a width, in a second direction crossing the first direction, of 100 nm to 400 nm.

The second layer may have a height of 500 nm to 900 nm.

A width, in a second direction crossing the first direction, of the first layer may be greater than a width, in the second direction, of the second layer, and a height of the first layer may be smaller than a height of the second layer.

The first layer and the second layer of each of the plurality of nanostructures may have a cross-sectional shape of a circular shape, an elliptical shape, a square shape, or a polygonal shape.

The first layer and the second layer of each of the plurality of nanostructures may include any one of GaN, TiO2, or SiN.

The light-emitting device may further include a reflective layer on at least one of a lateral surface of the vertical stack structure or a lower surface of the vertical stack structure.

The light-emitting device may further include an anti-reflection layer on the plurality of nanostructures.

The light-emitting device may further include a microlens on the plurality of nanostructures.

The light-emitting device may further include a fence on lateral surfaces of the plurality of nanostructures.

According to an aspect of the disclosure, a light-emitting device may include: a vertical stack structure including a first epitaxial structure, a second epitaxial structure on the first epitaxial structure in a first direction, and a third epitaxial structure on the second epitaxial structure in the first direction; a separation layer on the third epitaxial structure in the first direction; a plurality of first nanostructures on the separation layer; a plurality of second nanostructures on the separation layer; and a background medium between the plurality of first nanostructures and between the plurality of second nanostructures, wherein each of the plurality of first nanostructures includes a first layer and a second layer on the first layer, wherein the plurality of first nanostructures includes: a first-first nanostructure; and a second-first nanostructure that is closer than the first-first nanostructure to a center, in a second direction crossing the first direction, of the light-emitting device, wherein a width of the second layer of the second-first nanostructure in the second direction is smaller than a width of the second layer of the first-first nanostructure in the second direction, wherein each of the plurality of second nanostructures includes a single layer and does not include the second layer.

According to an aspect of the disclosure, a display apparatus may include: a light-emitting device including: a vertical stack structure including a first epitaxial structure, a second epitaxial structure on the first epitaxial structure in a first direction, and a third epitaxial structure on the second epitaxial structure in the first direction; a separation layer on the third epitaxial structure in the first direction; a plurality of nanostructures on the separation layer in the first direction; and a background medium between the plurality of nanostructures; and a driving device configured to drive the light-emitting device, wherein each of the plurality of nanostructures includes a first layer and a second layer on the first layer in the first direction.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a light-emitting device according to an embodiment;

FIGS. 2A and 2B are views illustrating finite-difference time-domain (FDTD) simulation field profiles of a light-emitting device according to an embodiment;

FIGS. 3A and 3B are views illustrating FDTD simulation field profiles of a light-emitting device according to a comparative example;

FIG. 4 is an enlarged view illustrating a portion A of the light-emitting device illustrated in FIG. 1;

FIGS. 5A and 5B are views illustrating FDTD simulation field profiles of a nanostructure according to an embodiment;

FIGS. 6A and 6B are views illustrating FDTD simulation field profiles of a nanostructure according to an embodiment;

FIG. 7 is a cross-sectional view illustrating a light-emitting device according to an embodiment;

FIG. 8 is a cross-sectional view illustrating a light-emitting device according to an embodiment;

FIG. 9 is a cross-sectional view illustrating a light-emitting device according to an embodiment;

FIG. 10 is a cross-sectional view illustrating a light-emitting device according to an embodiment;

FIG. 11 is a cross-sectional view illustrating a light-emitting device according to an embodiment;

FIG. 12 is a cross-sectional view illustrating a display apparatus according to an embodiment;

FIG. 13 is a view illustrating a method of manufacturing a light-emitting device, according to an embodiment;

FIG. 14 is a block diagram schematically illustrating an electronic apparatus including a display apparatus, according to an embodiment;

FIG. 15 is a view illustrating an example in which a display apparatus is applied to a mobile device, according to an embodiment;

FIG. 16 is a view illustrating an example in which a display apparatus is applied to a vehicle, according to an embodiment;

FIG. 17 is a view illustrating an example in which a display apparatus is applied to augmented reality glasses or virtual reality glasses, according to an embodiment;

FIG. 18 is a view illustrating an example in which a display apparatus is applied to signage according to an embodiment; and

FIG. 19 is view illustrating an example in which a display apparatus is applied to a wearable display according to an embodiment.

### DETAILED DESCRIPTION

Reference will now be made in detail to embodiments of the disclosure, examples of which are illustrated in the accompanying drawings, wherein like reference numerals refer to like elements throughout. In this regard, embodiments of the disclosure may have different forms and should not be construed as being limited to the descriptions set forth herein. Accordingly, example embodiments are merely described below, by referring to the figures, to explain example aspects of the disclosure. As used herein, the term “and/or” includes any and all combinations of one or more of the associated listed items. Expressions such as “at least one of,” when preceding a list of elements, modify the entire list of elements and do not modify the individual elements of the list. For example, the expression, "at least one of A, B, or C," should be understood as including only A, only B, only C, both A and B, both A and C, both B and C, or all of A, B, and C.

Hereinafter, a light-emitting device and a display apparatus including the light-emitting device will be described with reference to the accompanying drawings. In the drawings, the sizes of elements may be exaggerated for clarity of illustration. In addition, embodiments described herein are for illustrative purposes only, and various modifications may be made therein without departing from the spirit and scope of the disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present. The terms of a singular form may include plural forms unless otherwise mentioned. It will be further understood that the terms “comprises” (or “includes”) and/or “comprising” (or “including”) used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in any appropriate order unless described to the contrary, and are not limited to the stated order thereof.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples and terms are just used herein to describe example aspects of the disclosure and should not be considered for purposes of limitation.

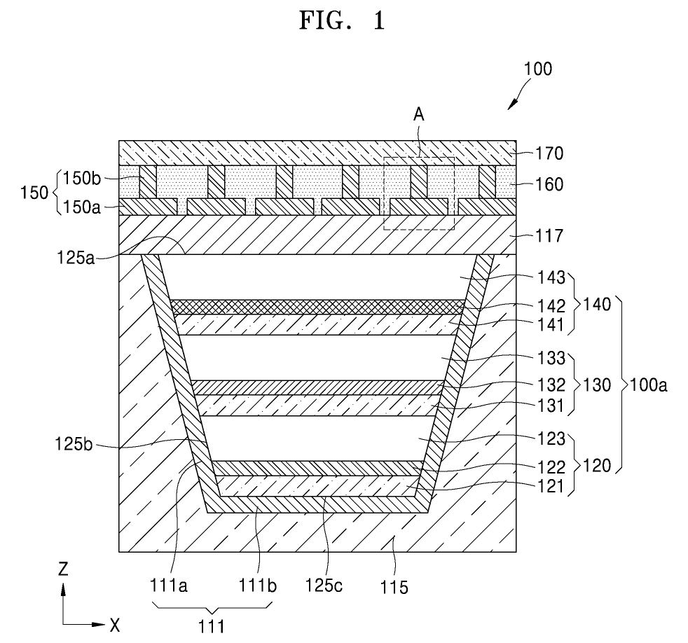

FIG. 1 is a cross-sectional view illustrating a light-emitting device 100 according to an embodiment.

Referring to FIG. 1, the light-emitting device 100 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of nanostructures 150 provided on the separation layer 117; and a background medium 160 filled between the nanostructures 150.

The first epitaxial structure 120 may have a structure in which a first semiconductor layer 121 of a first conductivity type, an active layer 122, and a second semiconductor layer 123 of a second conductivity type are sequentially stacked. The first epitaxial structure 120 may be configured to emit red light.

The second epitaxial structure 130 may have a structure in which a first semiconductor layer 131 of the first conductivity type, an active layer 132, and a second semiconductor layer 133 of the second conductivity type are sequentially stacked. The second epitaxial structure 130 may be configured to emit green light.

The third epitaxial structure 140 may have a structure in which a first semiconductor layer 141 of the first conductivity type, an active layer 142, and a second semiconductor layer 143 of the second conductivity type are sequentially stacked. The third epitaxial structure 140 may be configured to emit blue light.

The first semiconductor layers 121, 131, and 141 may be doped with a dopant of the first conductivity type, and the second semiconductor layers 123, 133, and 143 may be doped with a dopant of the second conductivity type that is electrically opposite to the first conductivity type. For example, the first semiconductor layers 121, 131, and 141 may be doped with an n-type dopant, and the second semiconductor layers 123, 133, and 143 may be doped with a p-type dopant. Alternatively, the first semiconductor layers 121, 131, and 141 may be doped with a p-type dopant, and the second semiconductor layers 123, 133, and 143 may be doped with an n-type dopant. Either the first semiconductor layers 121, 131, and 141 or the second semiconductor layers 123, 133, and 143 may be Group III-V compound semiconductor layers doped with an n-type dopant, and the others may be Group III-V compound semiconductor layers doped with a p-type dopant.

The active layers 122, 132, and 142 may generate light by recombining electrons and holes supplied from the first semiconductor layers 121, 131, and 141 and the second semiconductor layers 123, 133, and 143. To this end, the active layers 122, 132, and 142 may each have a quantum well structure in which a quantum well is disposed between barriers. The wavelength of light generated in the active layers 122, 132, and 142 may be determined depending on the energy bandgap of a material forming the quantum wells in the active layers 122, 132, and 142. Each of the active layers 122, 132, and 142 may have only a single quantum well, or may have a multi-quantum well (MQW) structure in which a plurality of quantum wells are arranged. The energy of the quantum wells in a conduction band may be selected to be lower than the energy of the barriers. To this end, the barriers and the quantum wells of the active layers 122, 132, and 142 may include different compound semiconductors or compound semiconductors having different compositions.

The first semiconductor layers 121, 131, and 141, the active layers 122, 132, and 142, and the second semiconductor layers 123, 133, and 143 may include, for example, Group III-V compound semiconductors based on GaN. For example, the first semiconductor layers 121, 131, and 141, the active layers 122, 132, and 142, and the second semiconductor layers 123, 133, and 143 may include Group III-V compound semiconductors such as GaN, InGaN, AlInGaN, or AlGaInP, and the first semiconductor layers 121, 131, and 141 and the second semiconductor layers 123, 133, and 143 may be doped with dopants of opposite types from each other.

For example, the first semiconductor layers 121, 131, and 141 and the second semiconductor layers 123, 133, and 143 may include GaN and may be doped with dopants of opposite types from each other. That is, the first semiconductor layers 121, 131, and 141 may include n-type doped GaN layers, and the second semiconductor layers 123, 133, and 143 may include p-type doped GaN layers. In another example, the first semiconductor layers 121, 131, and 141 may include p-type doped GaN layers, and the second semiconductor layers 123, 133, and 143 may include n-type doped GaN layers. The active layers 122, 132, and 142 may include, for example, InGaN, and the composition ratio of In and Ga in the active layers 122, 132, and 142 may be varied depending on an intended emission wavelength.

In the first epitaxial structure 120, the second epitaxial structure 130, and the third epitaxial structure 140, the active layers 122, 132, and 142 may each have, for example, a structure in which a first barrier, a quantum well, and a second barrier are stacked. The first barrier may be, for example, a GaN barrier, and may or may not be doped with silicon (Si). The quantum well may have a single quantum well structure or a MQW structure. For example, the quantum well may include a single-stacked or multiple-stack structure of InGaN/GaN or InGaN/GaN/AlGaN. In InₓGa₁₋ₓN forming the stack structure of the quantum well, the composition ratio of indium (In) and gallium (Ga) may vary depending on an emission wavelength. GaN in the stack structure of the quantum well may or may not be doped with Si.

For example, when red, green, and blue light are generated respectively in the first epitaxial structure 120, the second epitaxial structure 130, and the third epitaxial structure 140, the active layer 132 of the second epitaxial structure 130 and the active layer 142 of the third epitaxial structure 140 may include or may not include AlGaN, and the active layer 122 of the first epitaxial structure 120 may not include AlGaN. That is, in each of the active layers 132 and 142 of the second epitaxial structure 130 and the third epitaxial structure 140, the quantum well may include a single-stacked or multiple-stack structure of InₓGa₁₋ₓN/GaN or InₓGa₁₋ₓN/GaN/AlGaN, and in the active layer 122 of the first epitaxial structure 120, the quantum well may include a single-stacked or multiple-stack structure of InₓGa₁₋ₓN/GaN.

The separation layer 117 may be provided on the third epitaxial structure 140. The separation layer 117 may be provided for securing a separation distance between the nanostructures 150 and the third epitaxial structure 140, and the nanostructures 150 may be provided on the separation layer 117.

The separation layer 117 may include, for example, a dielectric material. In another example, the separation layer 117 may include an air layer. For example, the separation layer 117 may include: a plurality of posts for securing a separation distance between the nanostructures 150 and the third epitaxial structure 140; and an air layer filling a free space between the nanostructures 150 and the third epitaxial structure 140.

The light-emitting device 100 may further include a reflective layer 115 surrounding at least one of a lateral surface 125b and a lower surface 125c of the vertical stack structure 100a. The reflective layer 115 may include, for example, a metallic material. In addition, the light-emitting device 100 may further include a passivation layer 111 to protect the vertical stack structure 100a from external physical or chemical agents. The passivation layer 111 may be provided between the vertical stack structure 100a and the reflective layer 115. FIG. 1 shows an example in which the reflective layer 115 and the passivation layer 111 surround the lateral surface 125b and the lower surface 125c of the vertical stack structure 100a. The passivation layer 111 may include a lateral portion 111a positioned between the reflective layer 115 and the lateral surface 125b of the vertical stack structure 100a, and a lower portion 111b positioned between the reflective layer 115 and the lower surface 125c of the vertical stack structure 100a.

A considerable amount of light emitted from each of the active layers 122, 132, and 142 of the first epitaxial structure 120, the second epitaxial structure 130, and the third epitaxial structure 140 of the vertical stack structure 100a may be totally internally reflected at an upper surface 125a of the vertical stack structure 100a, and proceed back into the vertical stack structure 100a. In addition, when the reflective layer 115 surrounds the lateral surface 125b and the lower surface 125c of the vertical stack structure 100a as illustrated in FIG. 1, light passing through the lateral surface 125b and the lower surface 125c (boundaries) of the vertical stack structure 100a may be reflected by the reflective layer 115 and proceed back into the vertical stack structure 100a.

Here, light incident at an angle less than a critical angle for total internal reflection on boundary surfaces of the vertical stack structure 100a, that is, the lateral surface 125b, the lower surface 125c, and the upper surface 125a, may be partially transmitted and partially reflected, and the reflected light may propagate within the vertical stack structure 100a. In addition, there may be transmitted light that passes through portions of the upper surface 125a that are not overlapping with the nanostructures 150. However, the transmitted light may be weaker than light that is concentrated at and extracted through the nanostructures 150.

As described above, light emitted from each of the first epitaxial structure 120, the second epitaxial structure 130, and the third epitaxial structure 140 of the vertical stack structure 100a may propagate inside the vertical stack structure 100a due to total internal reflection and reflection by the reflective layer 115, and may then be refracted and emitted, at an angle less than the critical angle for total internal reflection, through the nanostructures 150 provided above the upper surface 125a of the vertical stack structure 100a.

The nanostructures 150 may each include a first layer 150a and a second layer 150b provided on the first layer 150a. The first layer 150a and the second layer 150b of each of the nanostructures 150 may have various cross-sectional shapes. For example, the cross-sectional shape of each of the first layer 150a and the second layer 150b of each of the nanostructures 150 may be any one of a circular shape, an elliptical shape, a square shape, or a polygonal shape.

The second layer 150b may be provided on a center portion of the first layer 150a. The expression “the second layer 150b may be provided on a center portion of the first layer 150a” indicates that the center of a lower surface of the second layer 150b, which is in contact with the first layer 150a, is aligned (e.g., overlapping) with the center of an upper surface of the first layer 150a, which is in contact with the second layer 150b. The height of the first layer 150a may be less than the height of the second layer 150b. For example, the height of the first layer 150a may be 400 nm or less. For example, the height of the first layer 150a may be 500 nm or less. For example, the height of the second layer 150b may be from about 500 nm to about 900 nm.

The width (e.g., the cross-sectional diameter) of the first layer 150a in a horizontal direction (e.g., the X-direction) may be greater than the width (e.g., the cross-sectional diameter) of the second layer 150b in the horizontal direction (e.g., the X-direction). For example, the width (e.g., the cross-sectional diameter) of the first layer 150a may be from about 300 nm to about 600 nm. For example, the width (e.g., the cross-sectional diameter) of the second layer 150b may be from about 100 nm to about 400 nm.

Each of the first layer 150a and the second layer 150b of each of the nanostructures 150 may include any one of GaN, TiO₂, or SiN. The nanostructures 150 may be arranged at a uniform pitch. For example, the pitch of the nanostructures 150 may be from about 500 nm to about 800 nm.

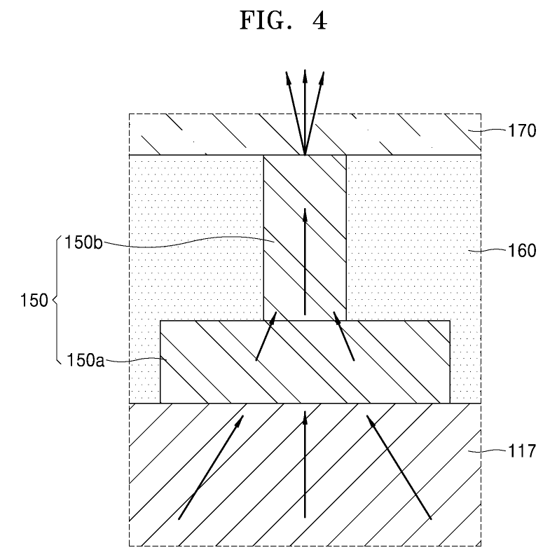

A significant amount of light of first to third wavelengths respectively generated in the active layers 122, 132, and 142 of the first to third epitaxial structures 120, 130, and 140 may be totally internally reflected at the upper surface 125a of the vertical stack structure 100a and may be reflected by the reflective layer 115 surrounding the lateral surface 125b and the lower surface 125c of the vertical stack structure 100a, thereby propagating inside the vertical stack structure 100a and then being emitted through the upper surface 125a of the vertical stack structure 100a as being refracted at an angle less than the critical angle for total internal reflection. In this process, as described below with reference to FIG. 4, light may be primarily extracted through the nanostructures 150 formed above the vertical stack structure 100a.

Because the nanostructures 150 each include the first layer 150a and the second layer 150b provided on the first layer 150a, the nanostructures 150 may increase the efficiency of light extraction from the vertical stack structure 100a. The nanostructures 150 may be capable of decreasing the divergence angle of emitted light. Thus, for example, when the light-emitting device 100 of the embodiment is applied as a micro-LED to implement a high-resolution micro-LED display, the interval between micro-LEDs may be reduced, and the amount of light required to implement an augmented reality (AR) display may be secured.

Although FIG. 1 illustrates an example in which the nanostructures 150 have the same height and the same cross-sectional size as each other, embodiments are not limited thereto. In addition, although FIG. 1 illustrates six nanostructures 150, the number of nanostructures 150 is not limited thereto. For example, two or more nanostructures 150 may be provided.

The background medium 160 may cover the nanostructures 150. The refractive index of a material included in the nanostructures 150 may be greater than the refractive index of a material included in the background medium 160.

The light-emitting device 100 may further include an anti-reflection layer 170 provided on the nanostructures 150. The anti-reflection layer 170 may increase transmittance for each of a plurality of wavelengths of light generated in the vertical stack structure 100a. The transmittance and reflectance of the anti-reflection layer 170 may be controlled by adjusting the material and thickness of the anti-reflection layer 170. The material and thickness of the anti-reflection layer 170 may be adjusted to reduce reflectance and increase transmittance for each of a plurality of wavelengths of light. For example, when the nanostructures 150 include a material that is different from a material included in the uppermost layer of the vertical stack structure 100a, the anti-reflection layer 170 may include a material having a refractive index that is not significantly different from or is similar to the refractive index of the nanostructures 150, The anti-reflection layer 170 may include, for example, Al₂O₃, SiN, TiO₂, ZrO₂, ZnO, Ta₂O₃, or SiON. In addition, FIG. 1 illustrates that the anti-reflection layer 170 is provided on upper portions of the nanostructures 150. In another example, however, the anti-reflection layer 170 may be provided on the upper surface 125a of the vertical stack structure 100a. In addition, the anti-reflection layer 170 may be disposed below the separation layer 117.

For example, the light-emitting device 100 of the embodiment may be manufactured as follows. For example, the third epitaxial structure 140, the second epitaxial structure 130, and the first epitaxial structure 120 may be sequentially grown on a substrate, and after electrode formation, the order of the third epitaxial structure 140, the second epitaxial structure 130, and the first epitaxial structure 120 may be reversed by flipping. In this manner, the vertical stack structure 100a may be formed. Then, after removing the substrate, the separation layer 117 and the nanostructures 150 may be formed on the third epitaxial structure 140, the background medium 160 may be filled between the nanostructures 150, and the anti-reflection layer 170 may be formed on the background medium 160. In this case, the nanostructures 150 may be formed through a photolithography process and a dry etching process. Prior to the flipping, the passivation layer 111 and the reflective layer 115 may be formed to surround the vertical stack structure 100a in which the third epitaxial structure 140, the second epitaxial structure 130, and the first epitaxial structure 120 are sequentially stacked.

In the light-emitting device 100 of the embodiment, the efficiency of light extraction from the vertical stack structure 100a may be improved because the nanostructures 150, each including the first layer 150a and the second layer 150b having different heights and diameters, are used for light extraction.

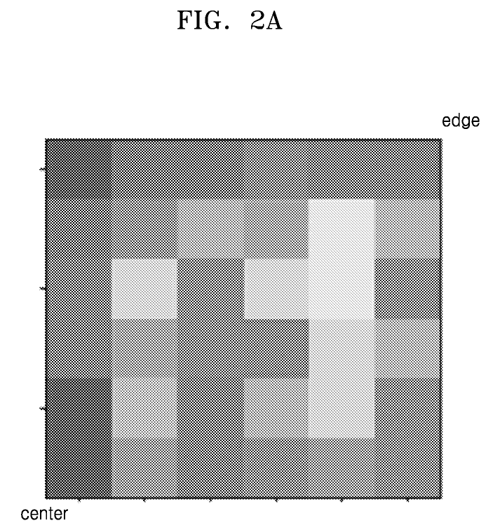

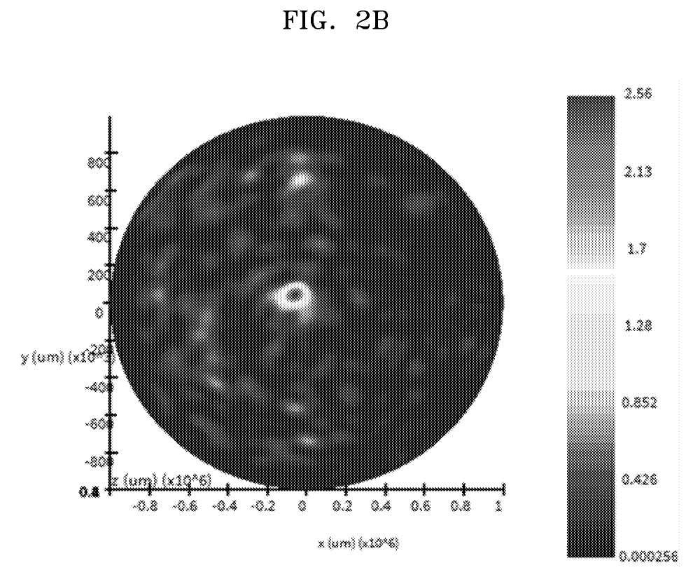

FIGS. 2A and 2B are views respectively illustrating finite-difference time-domain (FDTD) simulation light extraction efficiency and radiation pattern of the light-emitting device 100 according to an embodiment.

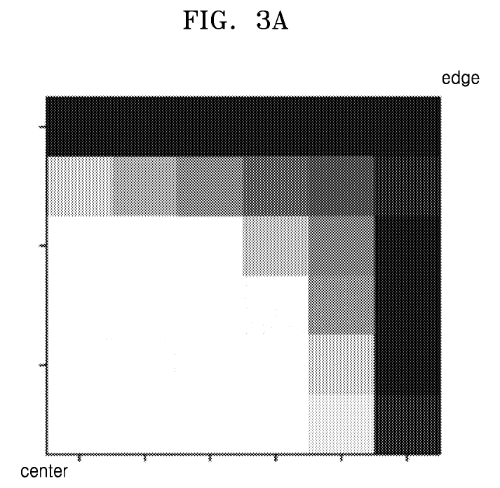

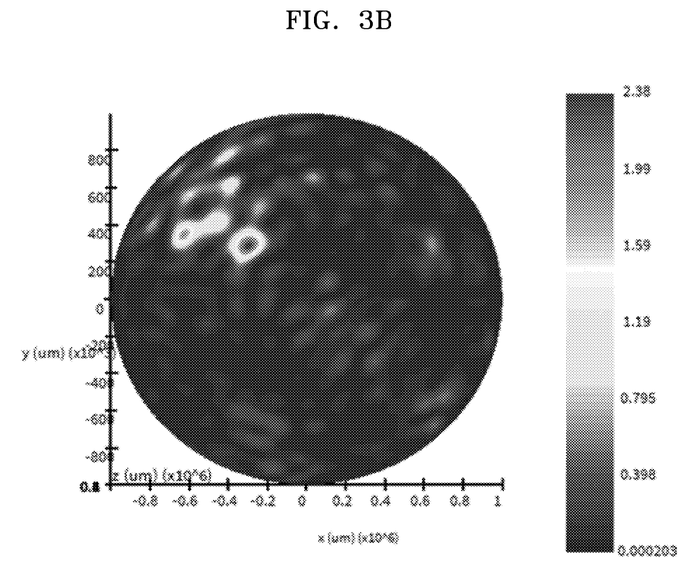

FIGS. 3A and 3B are views respectively illustrating FDTD simulation light extraction efficiency and radiation pattern of a light-emitting device according to a comparative example.

FIGS. 2A and 2B show simulation results of the light-emitting device 100 including the nanostructures 150 (refer to FIG. 1) on the upper surface 125a of the vertical stack structure 100a (refer to FIG. 1), and FIGS. 3A and 3B show simulation results of a light-emitting device including a microlens on an upper surface of a vertical stack structure.

Referring to FIGS. 2A and 2B, even when a point source is located at an edge portion of the light-emitting device 100 including the nanostructures 150 (refer to FIG. 1) on the upper surface 125a of the vertical stack structure 100a (refer to FIG. 1), light extraction is possible in a vertical direction, and thus, light extraction efficiency may be improved across the entire region of the light-emitting device 100.

However, referring to FIGS. 3A and 3B, in the light-emitting device including the microlens on the upper surface of the vertical stack structure, light extraction in the vertical direction is possible when a point source is located at a center portion of the light-emitting device, but light extraction in the vertical direction becomes difficult as the point source moves toward an edge portion of the light-emitting device.

It may be understood that the light-emitting device 100 of the embodiment may improve the efficiency of light extraction from the vertical stack structure 100a across the entire region of the light-emitting device 100 because the nanostructures 150, each including the first layer 150a and the second layer 150b having different heights and diameters, are used for light extraction.

FIG. 4 is an enlarged view illustrating a portion A of the light-emitting device 100 illustrated in FIG. 1.

Referring to FIG. 4, the light-emitting device 100 may include the nanostructures 150 each including the first layer 150a and the second layer 150b having different heights and diameters from each other. Light may be primarily extracted through the first layer 150a and the second layer 150b of each of the nanostructures 150 formed on the vertical stack structure 100a (refer to FIG. 1).

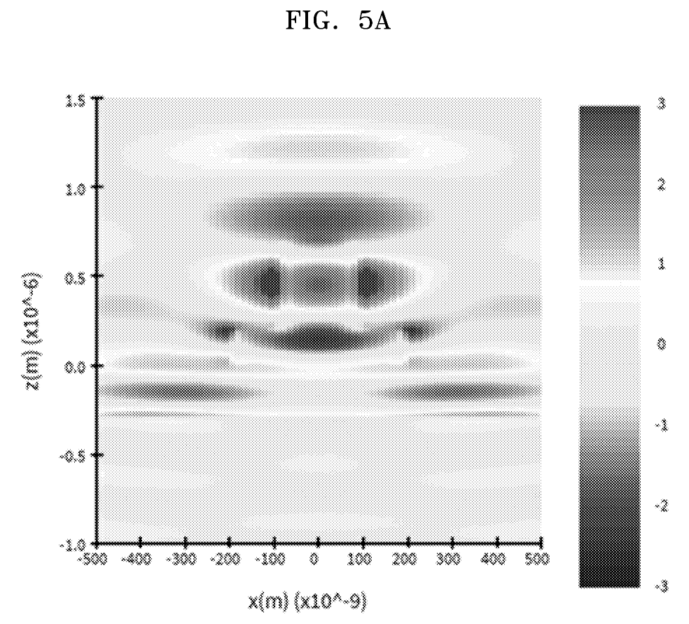

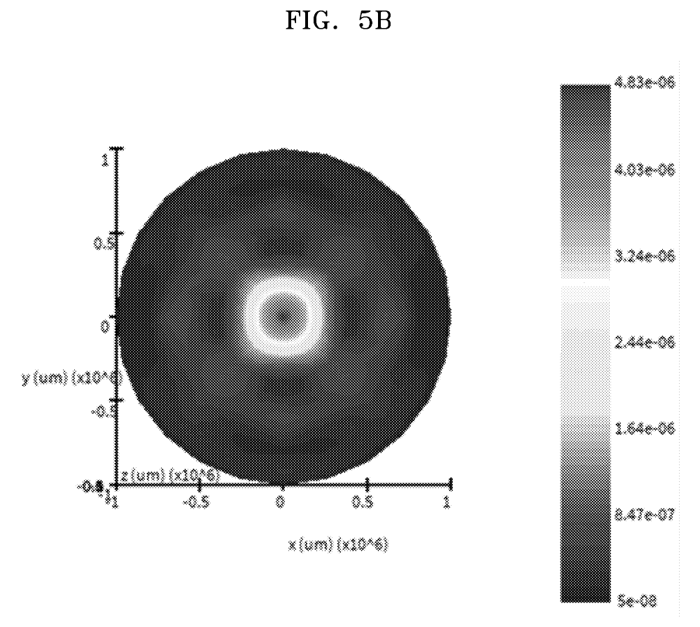

FIGS. 5A and 5B are views illustrating FDTD simulation field profiles and radiation pattern of a nanostructure according to an embodiment.

FIGS. 5A and 5B respectively show an electric field distribution and a far field radiation pattern when light is incident at an incident angle of 0 degree on the nanostructure 150 shown in FIG. 4, and it may be seen that radiation occurs centered around 0 degree.

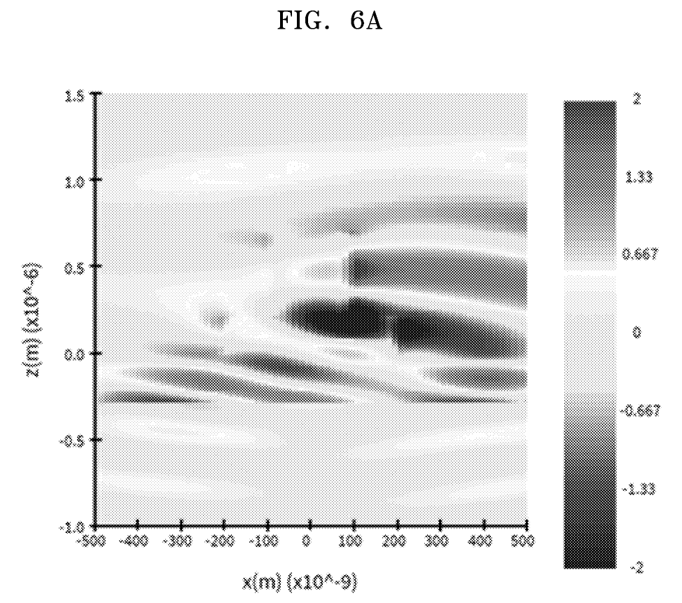

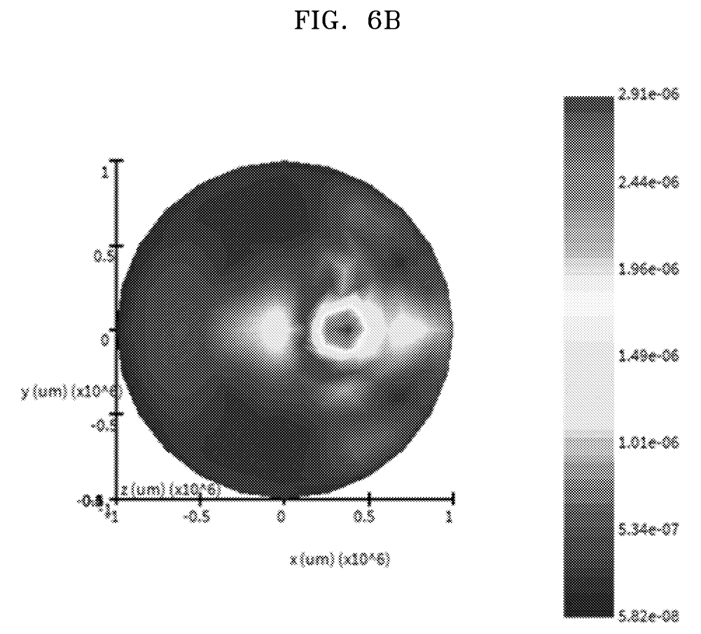

FIGS. 6A and 6B are views respectively illustrating FDTD simulation field profiles and radiation pattern of a nanostructure according to an embodiment.

FIGS. 6A and 6B respectively show an electric field distribution and a far field radiation pattern when light is incident at an incident angle of 20 degrees on the nanostructure 150 shown in FIG. 4, and it may be seen that when the incident angle is 20 degrees, radiation occurs centered around approximately 10 degrees, which is less than the incident angle.

It may be confirmed that the light-emitting device 100 of the embodiment may reduce the divergence angle of emitted light by extracting light through the nanostructures 150 each including the first layer 150a and the second layer 150b having different heights and diameters from each other.

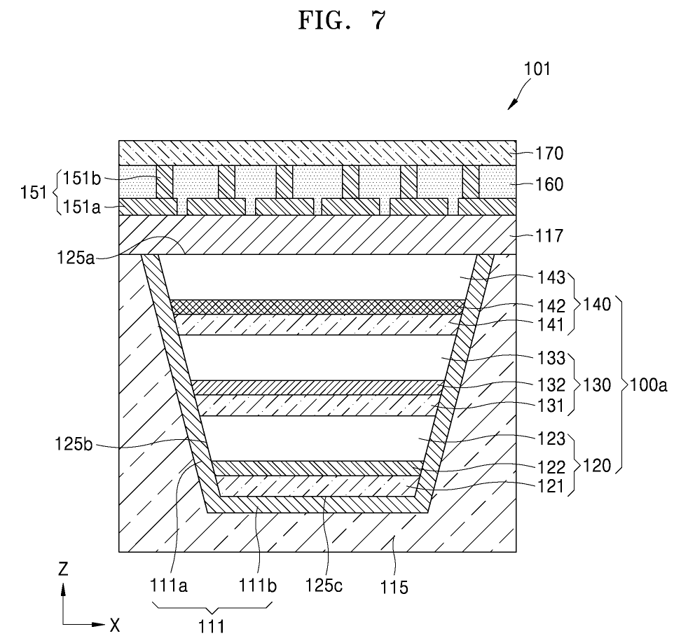

FIG. 7 is a cross-sectional view illustrating a light-emitting device 101 according to an embodiment.

Referring to FIG. 7, the light-emitting device 101 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of nanostructures 151 provided on the separation layer 117; and a background medium 160 filled between the nanostructures 151.

At least one of the nanostructures 151 may be configured such that a second layer 151b of the at least one nanostructure 151 is provided off-center from the center of a first layer 151a of the at least one nanostructure 151. As the nanostructures 151 are closer to the center of the light-emitting device 101 in the horizontal direction (e.g., the X-direction), second layers 151b of the nanostructures 151 may be closer to the centers of first layers 151a of the nanostructures 151 in the horizontal direction (e.g., the X-direction). As the nanostructures 151 are farther from the center of the light-emitting device 101 in the horizontal direction (e.g., the X-direction), the second layers 151b of the nanostructures 151 may be more offset from the centers of the first layers 151a of the nanostructures 151 toward the center of the light-emitting device 101 in the horizontal direction (e.g., the X-direction). This may improve light extraction efficiency.

The light-emitting device 101 shown in FIG. 7 may be the same as the light-emitting device 100 shown in FIG. 1, except that at least one of the nanostructures 151 is configured such that the second layer 151b of the at least one nanostructure 151 is provided off-center from the center of the first layer 151a of the at least one nanostructure 151. The description already provided with reference to FIG. 1 may not be repeated in the description of FIG. 7.

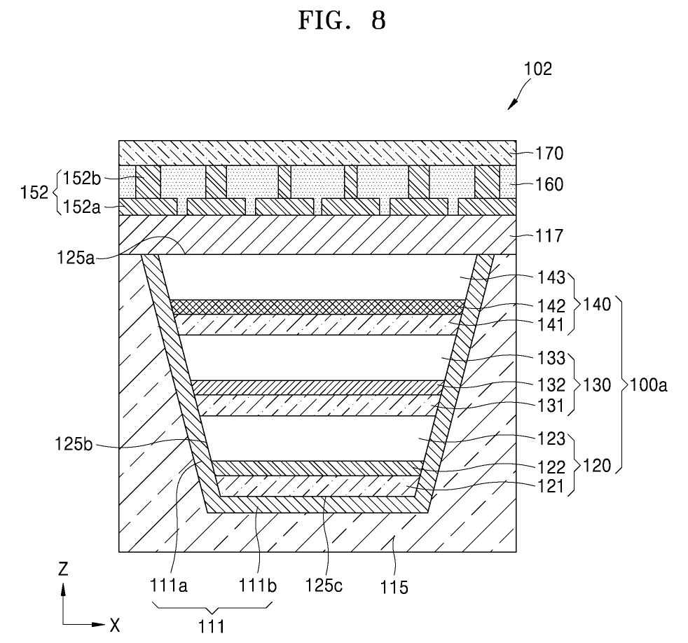

FIG. 8 is a cross-sectional view illustrating a light-emitting device 102 according to an embodiment.

Referring to FIG. 8, the light-emitting device 102 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of nanostructures 152 provided on the separation layer 117; and a background medium 160 filled between the nanostructures 152.

Second layers 152b of the nanostructures 152 may have different widths (e.g., diameters) in the horizontal direction (e.g., the X-direction). The closer the nanostructures 152 are to the center of the light-emitting device 102 in the horizontal direction (e.g., the X-direction), the smaller the widths (e.g., diameters) of the second layers 152b of the nanostructures 152 may be. This may improve light extraction efficiency.

The light-emitting device 102 shown in FIG. 8 may be the same as the light-emitting device 100 shown in FIG. 1, except that the second layers 152b of the nanostructures 152 have different widths (e.g., diameters) from each other. The description already provided with reference to FIG. 1 may not be repeated in the description of FIG. 8.

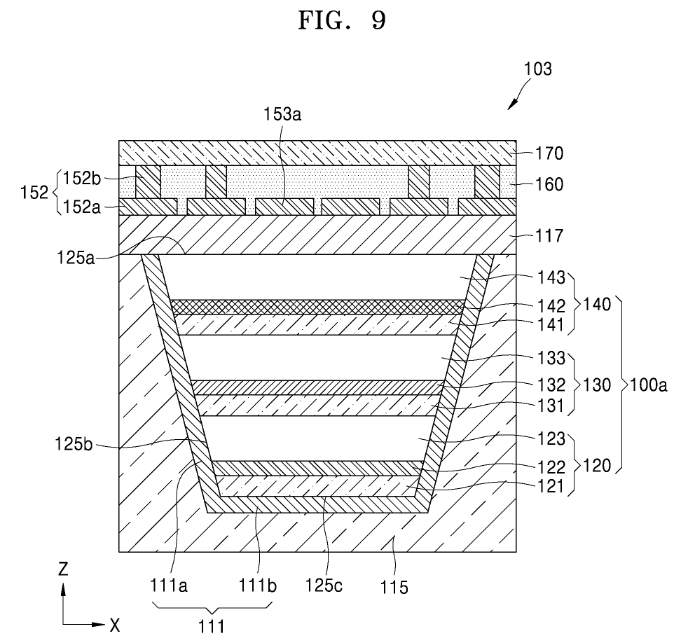

FIG. 9 is a cross-sectional view illustrating a light-emitting device 103 according to an embodiment.

Referring to FIG. 9, the light-emitting device 103 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of first nanostructures 152 and a plurality of second nanostructures 153a provided on the separation layer 117; and a background medium 160 filled between the first nanostructures 152 and the second nanostructures 153a.

The first nanostructures 152 may each include a first layer 152a and a second layer 152b provided on the first layer 152a. The closer the first nanostructures 152 are to the center of the light-emitting device 103 in the horizontal direction (e.g., the X-direction), the smaller the widths (e.g., diameters) of the second layers 152b of the first nanostructures 152 may be. The second nanostructures 153a may each be formed as a single layer, and may be closer than the first nanostructures 152 to the center of the light-emitting device 103 in the horizontal direction (e.g., the X-direction). This may improve light extraction efficiency.

The light-emitting device 103 shown in FIG. 9 may be the same as the light-emitting device 100 shown in FIG. 1, except that the light-emitting device 103 includes the first nanostructures 152 and the second nanostructures 153a. The description already provided with reference to FIG. 1 may not be repeated in the description of FIG. 9.

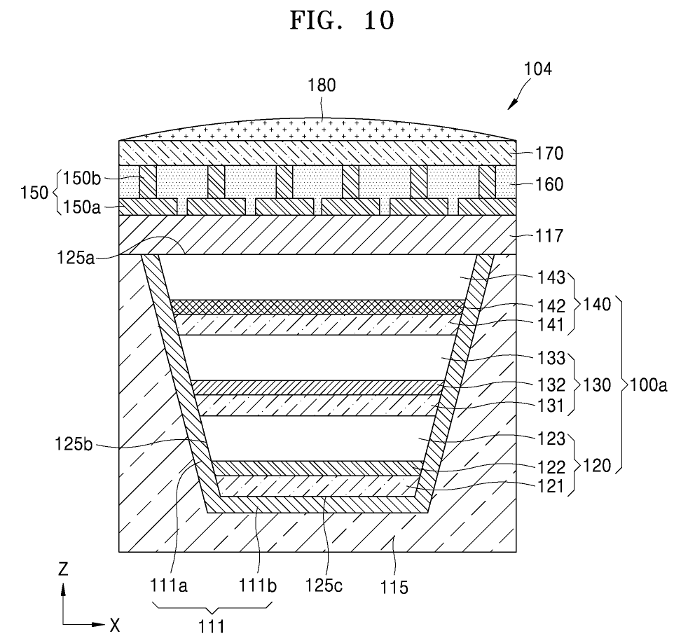

FIG. 10 is a cross-sectional view illustrating a light-emitting device 104 according to an embodiment.

Referring to FIG. 10, the light-emitting device 104 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of nanostructures 150 provided on the separation layer 117; a background medium 160 filled between the nanostructures 150; and a microlens 180 provided above the nanostructures 150.

Light extracted through the nanostructures 150 may be collimated by the microlens 180. Therefore, the divergence angle of light output from the light-emitting device 104 may be further reduced. The light-emitting device 104 may improve light extraction efficiency by providing the microlens 180 above the nanostructures 150.

The light-emitting device 104 shown in FIG. 10 may be the same as the light-emitting device 100 shown in FIG. 1, except that the light-emitting device 104 further includes the microlens 180 provided above the nanostructures 150. The description already provided with reference to FIG. 1 may not be repeated in the description of FIG. 10. In addition, although FIG. 10 illustrates that the microlens 180 is disposed on an anti-reflection layer 170, the microlens 180 may be disposed directly on the nanostructures 150 without the anti-reflection layer 170.

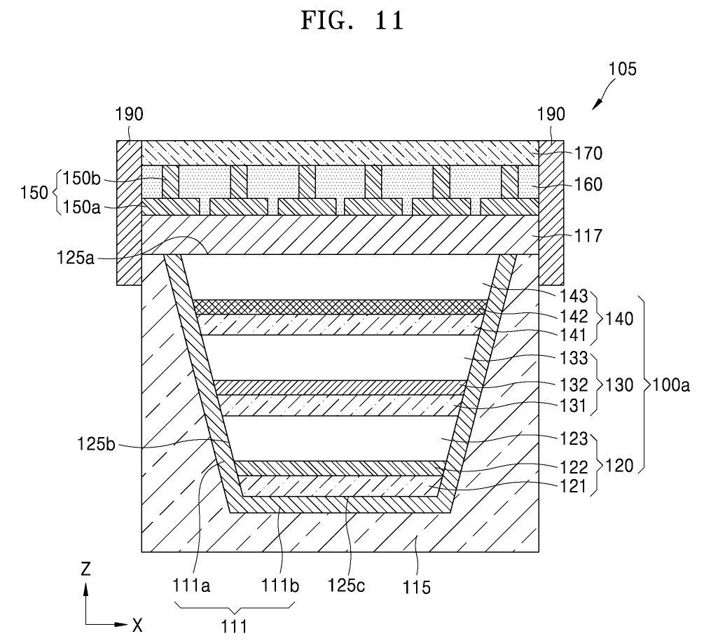

FIG. 11 is a cross-sectional view illustrating a light-emitting device 105 according to an embodiment.

Referring to FIG. 11, the light-emitting device 105 may include: a vertical stack structure 100a including a first epitaxial structure 120, a second epitaxial structure 130, and a third epitaxial structure 140 that are vertically and sequentially stacked; a separation layer 117 provided on the third epitaxial structure 140; a plurality of nanostructures 150 provided on the separation layer 117; a background medium 160 filled between the nanostructures 150; and a fence 190 provided on lateral surfaces of the nanostructures 150.

According to some embodiments, the fence 190 may also be provided on lateral surfaces of the reflective layer 115, the separation layer 117, the background medium 160, and/or the anti-reflection layer 170.

The light-emitting device 105 shown in FIG. 11 may be the same as the light-emitting device 100 shown in FIG. 1, except that the light-emitting device 105 further includes the fence 190 provided on the lateral surfaces of the nanostructures 150. The description already provided with reference to FIG. 1 may not be repeated in the description of FIG. 11.

The fence 190 may include, for example, a metallic material. In another example, the fence 190 may include an air layer. The fence 190 may be provided on the lateral surfaces of the nanostructures 150 to improve light extraction efficiency in an intended output direction.

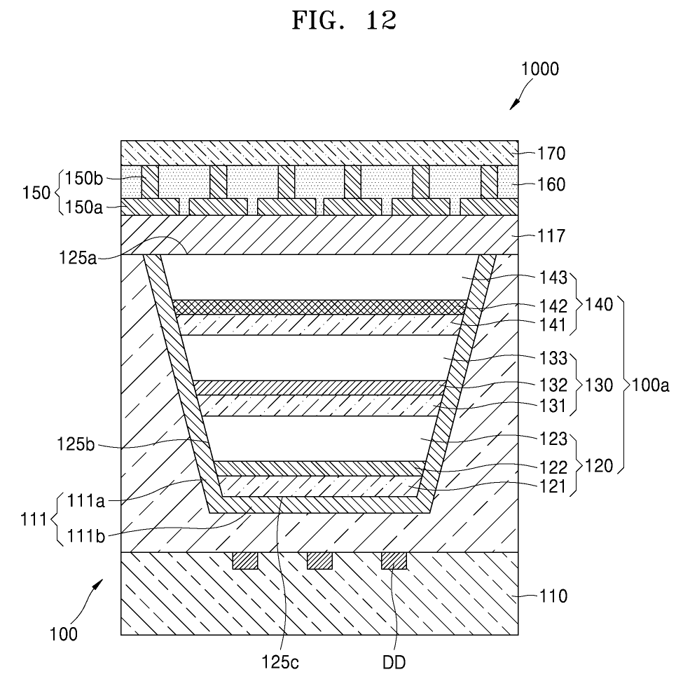

FIG. 12 is a cross-sectional view illustrating a display apparatus 1000 according to an embodiment.

Referring to FIG. 12, the display apparatus 1000 may include a light-emitting device 100, driving devices DD that drive the light-emitting device 100, and a backplane substrate 110 supporting the driving devices DD. The driving devices DD and the backplane substrate 110 may collectively be referred to as a backplane. The backplane may include: the driving devices DD configured to drive the light-emitting device 100; and the backplane substrate 110 supporting the driving devices DD. The light-emitting device 100 may be the same as the light-emitting device 100 shown in FIG. 1. The description already provided with reference to FIG. 1 may not be repeated in the description of FIG. 12.

The backplane substrate 110 may include an insulating material such as glass, an organic polymer, or quartz. In addition, the backplane substrate 110 may include a material having flexibility such that the backplane substrate 110 may be bent or folded. The backplane substrate 110 may have a single-layer or multi-layer structure.

The backplane substrate 110 may include at least one driving device DD. The at least one driving device DD may electrically drive epitaxial structures of the vertical stack structure 100a such as, for example, a first epitaxial structure 120, a second epitaxial structure 130, and a third epitaxial structure 140 of the vertical stack structure 100a. For example, the at least one driving device DD may include a transistor, a thin-film transistor, or a high electron mobility transistor (HEMT). However, the at least one driving device DD is not limited thereto and may further include a capacitor.

Owing to nanostructures 150, the display apparatus 1000 may improve the efficiency of light extraction from the vertical stack structure 100a of the light-emitting device 100 and may reduce the divergence angle of emitted light. Thus, the display apparatus 1000 may implement a high-resolution micro-LED display. Even when the interval between micro-LEDs is narrow, light quantity required for implementing an AR display may be secured because the divergence angle of light is controllable.

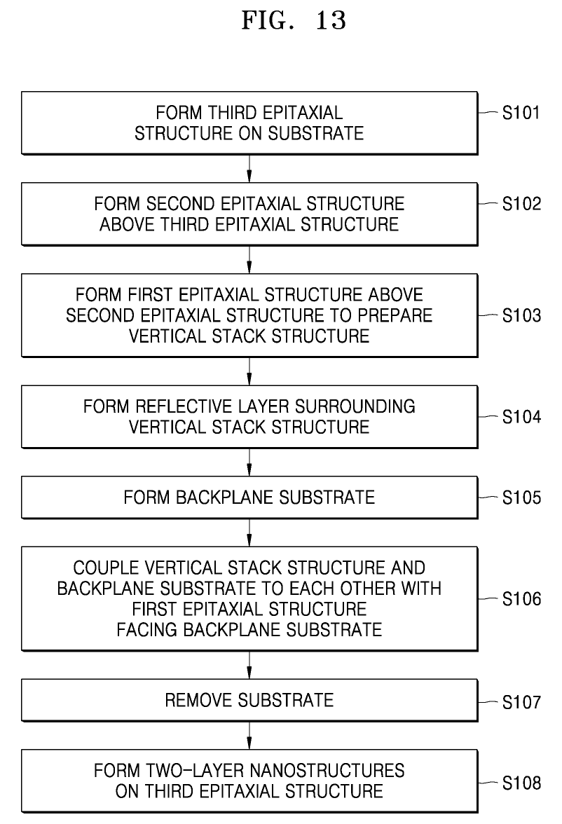

FIG. 13 is a view illustrating a method of manufacturing a display apparatus and a light-emitting device of the display apparatus according to an embodiment.

Referring to FIG. 13, a method of manufacturing a light-emitting device and a display apparatus according to an embodiment may include: forming a third epitaxial structure on a substrate (operation S101); forming a second epitaxial structure on the third epitaxial structure (operation S102); and forming a first epitaxial structure on the second epitaxial structure to prepare a vertical stack structure (operation S103). The substrate may be a growth substrate for growing epitaxial structures thereon and may include, for example, silicon, sapphire, or GaAs. However, embodiments are not limited thereto, and the substrate may include other materials.

The forming of the first, second, and third epitaxial structures (operations S101, S102, and S103) may each include forming a first-conductivity-type semiconductor layer, forming an active layer, and forming a second-conductivity-type semiconductor layer.

For example, the third epitaxial structure may emit blue light, the second epitaxial structure may emit green light, and the first epitaxial structure may emit red light. Here, the names of the first, second, and third epitaxial structures are the same as corresponding components shown in FIGS. 1 and 7 through 12. When the third, second, and first epitaxial structures are sequentially grown on the substrate, the third epitaxial structure, which may be formed first, may have relatively more defects than the first epitaxial structure, which may be formed later. Therefore, the first epitaxial structure for emitting red light, which has relatively low luminous efficiency, may be formed last.

After growing the vertical stack structure including the third, second, and first epitaxial structures that are sequentially stacked on the substrate, a reflective layer surrounding the vertical stack structure may be formed (operation S104). The reflective layer may be formed after a passivation layer for protecting the vertical stack structure is formed.

Next, a backplane substrate for implementing a display apparatus may be formed (operation S105). The backplane substrate may include at least one driving device. The vertical stack structure may be flipped such that the first epitaxial structure may face the backplane substrate, and is then may be bonded to the backplane substrate (operation S106). The vertical stack structure bonded to the backplane substrate may have a configuration in which the first, second, and third epitaxial structures are stacked in a vertical direction sequentially from the backplane side. As described above, the first epitaxial structure for red light emission may be formed last during the growth process, and thus, the vertical stack structure may be flipped and then bonded to the backplane substrate to have the first epitaxial structure on an upper side of the backplane substrate.

After bonding the vertical stack structure to the backplane substrate as described above, the substrate may be removed (operation S107). Then, two-layer nanostructures may be formed on the third epitaxial structure (operation S108).

A method of manufacturing a light-emitting device according to an embodiment may be a method of manufacturing a display apparatus according to an embodiment, except may omit the operation of the forming of the backplane substrate for implementing a display. In the method of manufacturing a light-emitting device according to the embodiment, the vertical stack structure may be coupled to a support substrate with the first epitaxial structure facing the support body, and then, the substrate may be removed. Thereafter, the two-layer nanostructures may be formed on the third epitaxial structure.

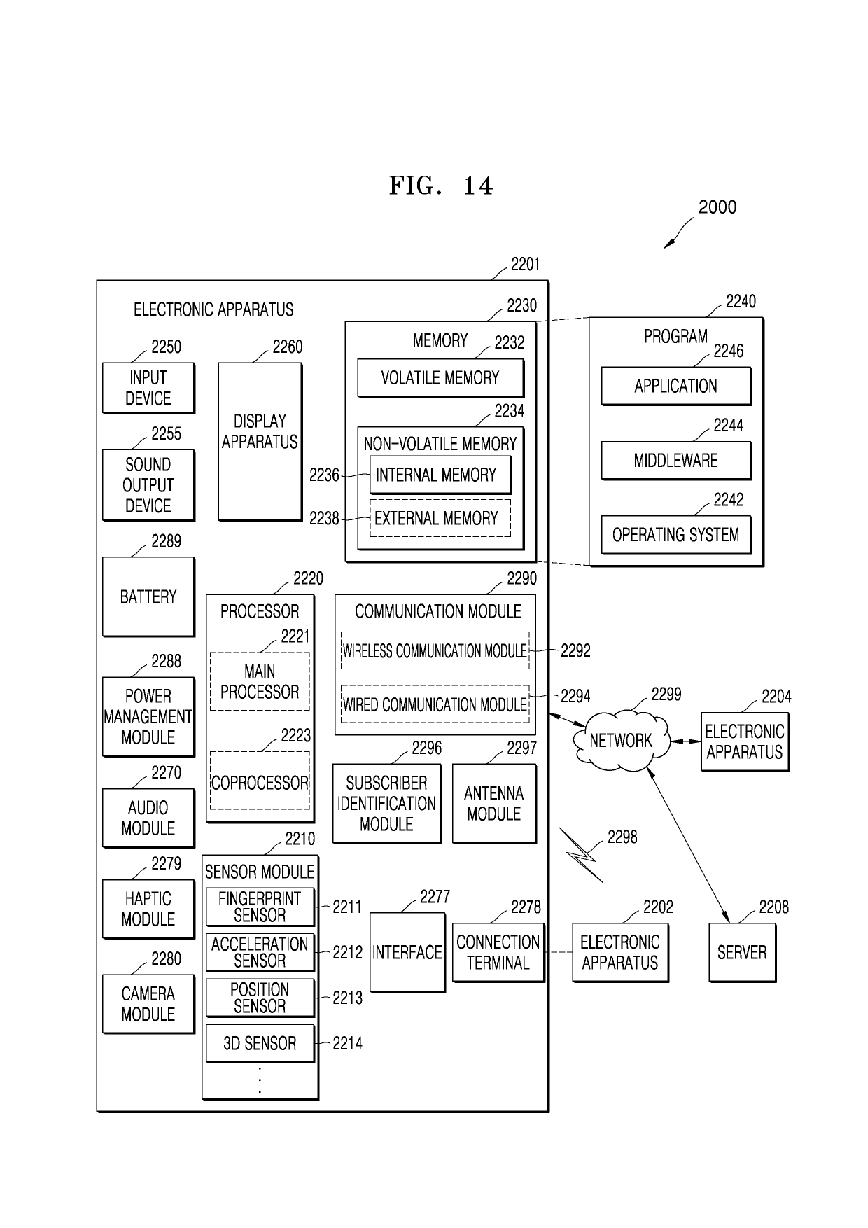

FIG. 14 is a block diagram schematically illustrating an electronic apparatus 2201 including a display apparatus 2260, according to an embodiment.

Referring to FIG. 14, in a network environment 2000, the electronic apparatus 2201 may communicate with another electronic apparatus 2202 through a first network 2298 (e.g., a short-range wireless communication network) or may communicate with another electronic apparatus 2204 and/or a server 2208 through a second network 2299 (e.g., a long-range wireless communication network). The electronic apparatus 2201 may communicate with the electronic apparatus 2204 through the server 2208. The electronic apparatus 2201 may include a processor 2220, a memory 2230, an input device 2250, a sound output device 2255, the display apparatus 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297. Some (e.g., the sensor module 2210 or the like) of the components of the electronic apparatus 2201 may be omitted, or other components may be added to the electronic apparatus 2201. Some of the components may be implemented as one integrated circuit. For example, a fingerprint sensor 2211, an iris sensor, an illuminance sensor, or the like, included in the sensor module 2210, may be embedded in the display apparatus 2260 (e.g., a display).

The processor 2220 may execute software (e.g., a program 2240) to control one or more other components (e.g., hardware or software components) of the electronic apparatus 2201 which are connected to the processor 2220, and the processor 2220 may perform various data processing or operations. As part of data processing or computation, the processor 2220 may load commands and/or data received from other components (e.g., the sensor module 2210, the communication module 2290, or the like) on a volatile memory 2232, process the commands and/or data stored in the volatile memory 2232, and store resulting data in a non-volatile memory 2234. The processor 2220 may include: a main processor 2221 (e.g., a central processing unit, an application processor, or the like); and a coprocessor 2223 (e.g., a graphics processing unit, an image signal processor, a sensor hub processor, a communication processor, or the like) that may be operated independently or in conjunction with the main processor 2221. The coprocessor 2223 may consume less power than the main processor 2221 and may perform a specialized function.

The coprocessor 2223 may control functions and/or states related to some of the components (e.g., the display apparatus 2260, the sensor module 2210, and the communication module 2290) of the electronic apparatus 2201, instead of the main processor 2221 while the main processor 2221 is in an inactive state (e.g., sleep mode) or together with the main processor 2221 while the main processor 2221 is in an active state (e.g., application-execution mode). The coprocessor 2223 (e.g., an image signal processor, a communication processor, or the like) may be implemented as part of a functionally related component (e.g., the camera module 2280 or the communication module 2290).

The memory 2230 may store various pieces of data required by the components (e.g., the processor 2220, the sensor module 2210, or the like) of the electronic apparatus 2201. For example, the data may include: software (e.g., the program 2240); and instruction input data and/or output data which are related to the software. The memory 2230 may include the volatile memory 2232 and/or the non-volatile memory 2234.

The program 2240 may be stored as software in the memory 2230 and may include an operating system 2242, middleware 2244, and/or an application 2246.

The input device 2250 may receive, from outside the electronic apparatus 2201 (e.g., a user), commands and/or data to be used in the components (e.g., the processor 2220) of the electronic apparatus 2201. The input device 2250 may include a microphone, a mouse, a keyboard, and/or a digital pen (e.g., a stylus pen).

The sound output device 2255 may output a sound signal to the outside of the electronic apparatus 2201. The sound output device 2255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display apparatus 2260 may provide information to the outside of the electronic apparatus 2201 in a visual manner. The display apparatus 2260 may include a device such as a display, a hologram device, or a projector, and a control circuit for controlling the device. The display apparatus 2260 may include: touch circuitry configured to detect touches; and/or a sensor circuit (e.g., a pressure sensor) configured to measure the magnitudes of forces generated by touches.

The audio module 2270 may convert a sound into an electric signal or may conversely convert an electric signal into a sound. The audio module 2270 may acquire a sound through the input device 2250, or may output a sound through the sound output device 2255 and/or the speaker and/or headphone of another electronic apparatus (e.g., the electronic apparatus 2202) which are directly or wirelessly connected to the electronic apparatus 2201.

The sensor module 2210 may detect an operating state (e.g., the power or the temperature) of the electronic apparatus 2201 or an external environmental state (e.g., a user state) and may generate an electrical signal and/or a data value corresponding to the detected state. The sensor module 2210 may include the fingerprint sensor 2211, an acceleration sensor 2212, a position sensor 2213, a 3D sensor 2214, or the like. In addition, the sensor module 2210 may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor.

The 3D sensor 2214 may emit light toward an object and analyze light reflected from the object to sense characteristics such as the shape and motion of the object.

The interface 2277 may support one or more designated protocols that may be used by the electronic apparatus 2201 for directly or wirelessly connection with another electronic apparatus (e.g., the electronic apparatus 2202). The interface 2277 may include a high-definition multimedia Interface (HDMI), a universal serial bus (USB) interface, a secure digital (SD) card interface, and/or an audio interface.

A connection terminal 2278 may include a connector through which the electronic apparatus 2201 may be physically connected to another electronic apparatus (e.g., the electronic apparatus 2202). The connection terminal 2278 may include an HDMI connector, an USB connector, an SD card connector, and/or an audio connector (e.g., a headphone connector).

The haptic module 2279 may convert an electrical signal into a mechanical stimulus (e.g., vibration, movement, or the like) or an electrical stimulus that a user may perceive by the tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly of the camera module 2280 may collect light coming from an object to be imaged.

The power management module 2288 may manage power supplied to the electronic apparatus 2201. The power management module 2288 may be implemented as part of a power management integrated circuit (PMIC).

The battery 2289 may supply power to the components of the electronic apparatus 2201. The battery 2289 may include non-rechargeable primary cells, rechargeable secondary cells, and/or fuel cells.

The communication module 2290 may support the establishment of a direct (wired) communication channel and/or a wireless communication channel between the electronic apparatus 2201 and another electronic apparatus (e.g., the electronic apparatus 2202, the electronic apparatus 2204, or the server 2208), and may support communication through the established communication channel. The communication module 2290 may include one or more communication processors that operate independently of the processor 2220 (e.g., an application processor) and support direct communication and/or wireless communication. The communication module 2290 may include: a wireless communication module 2292 (e.g., a cellular communication module, a short-range wireless communication module, or a global navigation satellite system (GNSS) communication module); and/or a wired communication module 2294 (e.g., a local area network (LAN) communication module or a power line communication module). The wireless communication module 2292 and the wired communication module 2294 may communicate with another electronic apparatus through the first network 2298 (for example, a short-range communication network such as Bluetooth, WiFi direct, or infrared data association (IrDA)), or the second network 2299 (for example, a long-range communication network such as a cellular network, the Internet, or a computer network (LAN, WAN, or the like)). Such various types of communication modules may be integrated into one component (single chip or the like) or may be implemented as a plurality of components (plural chips) separate from each other. The wireless communication module 2292 may identify and authenticate the electronic apparatus 2201 in a communication network such as the first network 2298 and/or the second network 2299 by using subscriber information (e.g., an international mobile subscriber identifier (IMSI)) stored in the subscriber identification module 2296.

The antenna module 2297 may transmit or receive signals and/or power to or from the outside (for example, other electronic apparatuses). An antenna may include a radiator which has a conductive pattern formed on a substrate (e.g., a PCB). The antenna module 2297 may include one or a plurality of such antennas. When the antenna module 2297 include a plurality of antennas, the communication module 2290 may select one of the plurality of antennas which is suitable for a communication method used in a communication network such as the first network 2298 and/or the second network 2299. Signals and/or power may be transmitted between the communication module 2290 and another electronic apparatus through the selected antenna. In addition to the antennas, other components (e.g., a radio-frequency integrated circuit (RFIC)) may be included as part of the antenna module 2297.

Some of the components may be connected to each other and exchange signals (e.g., commands or data) by an inter-peripheral communication scheme (e.g., a bus, general purpose input and output (GPIO), serial peripheral interface (SPI), or mobile industry processor interface (MIPI)).

Commands or data may be transmitted between the electronic apparatus 2201 and the (external) electronic apparatus 2204 through the server 2208 connected to the second network 2299. The other electronic apparatuses 2202 and 2204 and the electronic apparatus 2201 may be the same type of electronic apparatus or may be different types of electronic apparatuses. All or some of operations of the electronic apparatus 2201 may be executed in one or more of the other electronic apparatuses 2202 and 2204, and the server 2208. For example, when the electronic apparatus 2201 needs to perform a certain function or service, the electronic apparatus 2201 may request one or more other electronic apparatuses to perform a part or all of the function or service instead of performing the function or service by itself. The one or more other electronic apparatuses receiving the request may perform an additional function or service related to the request, and may transmit results thereof to the electronic apparatus 2201. To this end, cloud computing, distributed computing, and/or client-server computing techniques may be used.

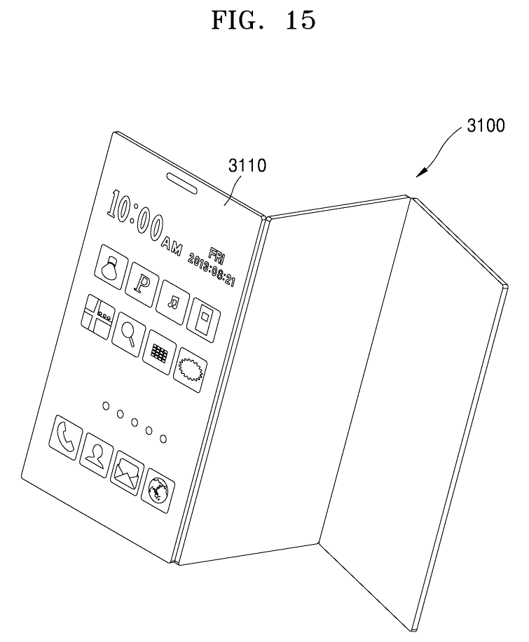

FIG. 15 is a view illustrating an example in which a display apparatus 3110 is applied to a mobile device 3100, according to an embodiment.

Referring to FIG. 15, the mobile device 3100 may include the display apparatus 3110, and the display apparatus 3110 may include the display apparatus 1000 described with reference to FIG. 12. The display apparatus 3110 may have a foldable structure such as a multi-foldable structure.

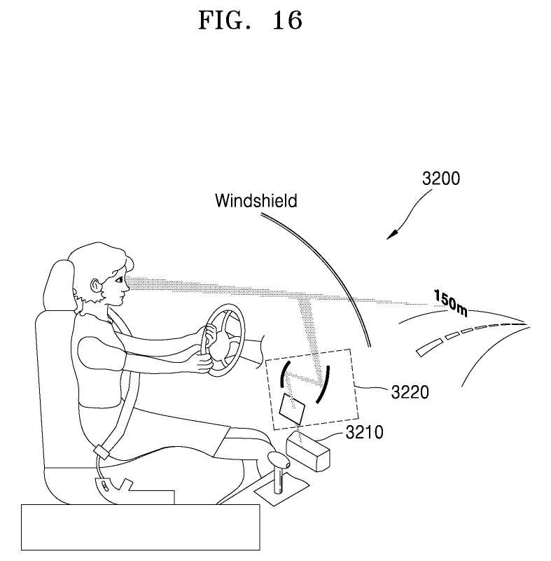

FIG. 16 is a view illustrating an example in which a display apparatus is applied to a vehicle, according to an embodiment.

Referring to FIG. 16, the display apparatus may be a vehicular head-up display apparatus 3200, and may include: a display 3210 provided in an region of the vehicle; and an optical path changing member 3220 configured to change the optical path of light such that a driver may see images generated by the display 3210.

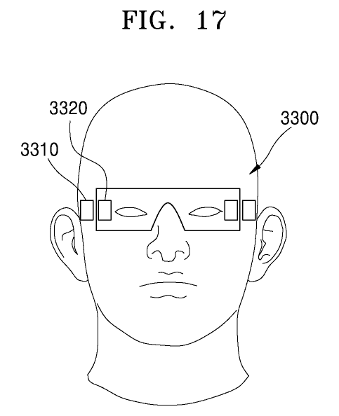

FIG. 17 is a view illustrating an example in which a display apparatus is applied to AR glasses 3300 or virtual reality glasses, according to an embodiment.

Referring to FIG. 17, the AR glasses 3300 may include: a projection system 3310 configured to form images; and waveguides 3320 configured to guide the images from projection system 3310 into the eyes of a user. The projection system 3310 may include the display apparatus 1000 described with reference to FIG. 12. For example, the waveguides 3320 may be provided in a frame of the AR glasses 3300.

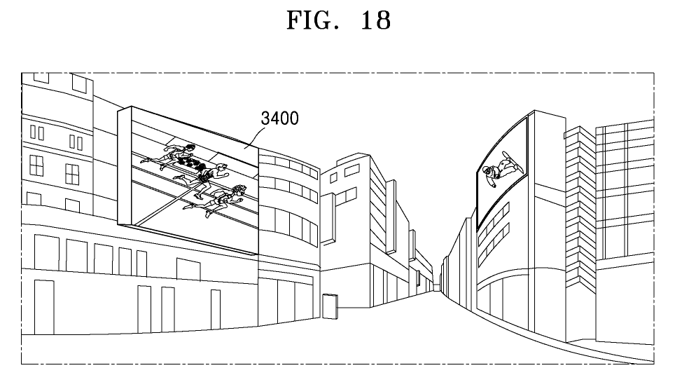

FIG. 18 is a view illustrating an example in which a display apparatus is applied to signage 3400 (e.g., a large signage) according to an embodiment.

Referring to FIG. 18, the signage 3400 may be used for outdoor advertisement using a digital information display and may control advertisement content and the like through a communication network. For example, the signage 3400 may be implemented through the electronic apparatus 2201 described with reference to FIG. 14.

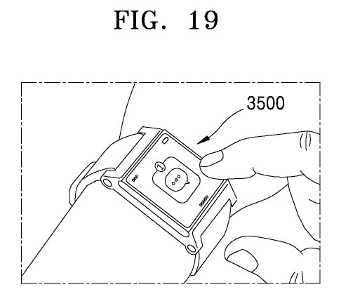

FIG. 19 is a view illustrating an example in which a display apparatus is applied to a wearable display 3500 according to an embodiment. The wearable display 3500 may include a display apparatus according to an embodiment and may be implemented through the electronic apparatus 2201 described with reference to FIG. 14.

The display apparatuses of the embodiments may be applied to various products such as a rollable TV and a stretchable display.

As described above, according to embodiments of the disclosure, a light-emitting device having improved light extraction efficiency by extracting light using nanostructures each including first and second layers having different heights and diameters, and a display apparatus including the light-emitting device, may be provided.

According to embodiments of the disclosure, the display apparatus may be applied to various electronic apparatuses.

According to the light-emitting device and the display apparatus including the light-emitting device, light may be extracted using the nanostructures each having first and second layers having different heights and diameters, and thus, the efficiency of light extraction from a vertical stack structure may be improved. While the light-emitting device and the display apparatus including the light-emitting device have been described according to embodiments with reference to the accompanying drawings, it will be understood by those of ordinary skill in the art that the embodiments are merely examples, and various modifications and other equivalent embodiments may be made therein. Therefore, the embodiments described herein should be considered in a descriptive sense only and not for purposes of limitation. The various modifications and equivalent embodiments are included within the spirit and scope of the disclosure.

Some aspects of non-limiting example embodiments described above may be summarized as follows.
(1) According to an embodiment, a light-emitting device may include a vertical stack structure including first to third epitaxial structures that are sequentially stacked, a separation layer provided on the third epitaxial structure, a plurality of nanostructures provided on the separation layer, and a background medium filled between the plurality of nanostructures, wherein each of the plurality of nanostructures may include a first layer and a second layer provided on the first layer.
(2) A center of the second layer may be aligned (e.g., overlapping) with a center of the first layer in each of the plurality of nanostructures.
(3) At least one of the plurality of nanostructures may be provided such that a center of the second layer may deviate from a center of the first layer in the at least one of the plurality of nanostructures.
(4) A nanostructure, from among the plurality of nanostructures, provided closer to a center of the light-emitting device may include a center of the second layer closer to a center of the first layer in the nanostructure.
(5) The second layers of the plurality of nanostructures may have different widths (e.g., diameters) from each other.
(6) A material included in the plurality of nanostructures may have a greater refractive index than a refractive index of a material included in the background medium.
(7) The plurality of nanostructures may be arranged at a pitch of about 500 nm to about 800 nm.
(8) The first layers may have a width (e.g., cross-sectional diameter) of about 300 nm to about 600 nm.
(9) The first layers may have a height of 400 nm or less.
(10) The second layers may have a width (e.g., cross-sectional diameter) of about 100 nm to about 400 nm.
(11) The second layers may have a height of about 500 nm to about 900 nm.
(12) The first layers may have a greater width (e.g., cross-sectional diameter) than a width (e.g., cross-sectional diameter) of the second layers, and the first layers may have a smaller height than a height of the second layers.
(13) Each of the first layers and the second layers of the plurality of nanostructures may have a cross-sectional shape selected from among a circular shape, an elliptical shape, a square shape, and a polygonal shape.
(14) Each of the first layers and the second layers of the plurality of nanostructures may include any one of GaN, TiO₂, or SiN.
(15) The light-emitting device may further include a reflective layer surrounding at least one of a lateral surface of the vertical stack structure or a lower surface of the vertical stack structure.
(16) The light-emitting device may further include an anti-reflection layer on the plurality of nanostructures.
(17) The light-emitting device may further include a microlens on the plurality of nanostructures.
(18) The light-emitting device may further include a fence on lateral surfaces of the plurality of nanostructures.
(19) According to an embodiment, a light-emitting device may include a vertical stack structure including first to third epitaxial structures that are sequentially stacked, a separation layer provided on the third epitaxial structure, a plurality of first nanostructures and a plurality of second nanostructures that are provided on the separation layer, and a background medium filled between the plurality of first nanostructures and the plurality of second nanostructures. Each of the plurality of first nanostructures may include a first layer and a second layer provided on the first layer. As the plurality of first nanostructures are closer to a center of the light-emitting device, the second layers of the plurality of first nanostructures may have smaller diameters. Each of the plurality of second nanostructures may include a single layer.
(20) According to an embodiment, a display apparatus may include the light-emitting device and a driving device configured to drive the light-emitting device.
(21) According to an embodiment, a method of manufacturing a light-emitting device may include: forming a vertical stack structure including a first epitaxial structure, a second epitaxial structure on the first epitaxial structure in a first direction, and a third epitaxial structure on the second epitaxial structure in the first direction; providing a separation layer on the third epitaxial structure in the first direction; providing a plurality of nanostructures on the separation layer in the first direction; and providing a background medium between the plurality of nanostructures, wherein each of the plurality of nanostructures comprises a first layer and a second layer on the first layer in the first direction.
(22) According to an embodiment, a method of manufacturing a display apparatus may include: the method of manufacturing the light-emitting device; and providing a backplane substrate on the vertical stack structure.

What is claimed is:

1. A light-emitting device comprising: a vertical stack structure comprising a first epitaxial structure, a second epitaxial structure on the first epitaxial structure in a first direction, and a third epitaxial structure on the second epitaxial structure in the first direction; a separation layer on the third epitaxial structure in the first direction; a plurality of nanostructures on the separation layer in the first direction; and a background medium between the plurality of nanostructures, wherein each nanostructure of the plurality of nanostructures comprises a first layer and a second layer on the first layer in the first direction.

2. The light-emitting device of claim 1, wherein, in each of the plurality of nanostructures, a center of the second layer is overlapping in the first direction with a center of the first layer.

3. The light-emitting device of claim 1, wherein a center, in a second direction crossing the first direction, of the second layer of a nanostructure from among the plurality of nanostructures is spaced from a center, in the second direction, of the first layer of the nanostructure.

4. The light-emitting device of claim 1, wherein the plurality of nanostructures comprises: a first nanostructure, wherein a center, in a second direction crossing the first direction, of the first layer of the first nanostructure is at a first distance from a center, in the second direction, of the first layer of the first nanostructure; and a second nanostructure that is closer than the first nanostructure to a center of the light-emitting device in the second direction, wherein a center, in the second direction, of the first layer of the second nanostructure is at a second distance from a center, in the second direction, of the first layer of the second nanostructure, and wherein the second distance is smaller than the first distance.

5. The light-emitting device of claim 1, wherein a width, in a second direction crossing the first direction, of the second layer of one of the plurality of nanostructures is different from a width, in the second direction, of the second layer of another one of the plurality of nanostructures.

6. The light-emitting device of claim 1, wherein a refractive index of a of the plurality of nanostructures is greater than a refractive index of a material of the background medium.

7. The light-emitting device of claim 1, wherein the plurality of nanostructures are arranged at a pitch of 500 nm to 800 nm.

8. The light-emitting device of claim 1, wherein the first layer has a width, in a second direction crossing the first direction, of 300 nm to 600 nm.

9. The light-emitting device of claim 1, wherein the first layer has a height of 400 nm or less.

10. The light-emitting device of claim 1, wherein the second layer has a width, in a second direction crossing the first direction, of 100 nm to 400 nm.

11. The light-emitting device of claim 1, wherein the second layer has a height of 500 nm to 900 nm.

12. The light-emitting device of claim 1, wherein a width, in a second direction crossing the first direction, of the first layer is greater than a width, in the second direction, of the second layer, and wherein a height of the first layer is smaller than a height of the second layer.

13. The light-emitting device of claim 1, wherein the first layer and the second layer of each of the plurality of nanostructures have a cross-sectional shape of a circular shape, an elliptical shape, a square shape, or a polygonal shape.

14. The light-emitting device of claim 1, wherein the first layer and the second layer of each of the plurality of nanostructures comprise any one of GaN, TiO₂ or SiN.

15. The light-emitting device of claim 1, further comprising a reflective layer on at least one of a lateral surface of the vertical stack structure or a lower surface of the vertical stack structure.

16. The light-emitting device of claim 1, further comprising an anti-reflection layer on the plurality of nanostructures.

17. The light-emitting device of claim 1, further comprising a microlens on the plurality of nanostructures.

18. The light-emitting device of claim 1, further comprising a fence on lateral surfaces of the plurality of nanostructures.

19. A light-emitting device comprising: a vertical stack structure comprising a first epitaxial structure, a second epitaxial structure on the first epitaxial structure in a first direction, and a third epitaxial structure on the second epitaxial structure in the first direction; a separation layer on the third epitaxial structure in the first direction; a plurality of first nanostructures on the separation layer; a plurality of second nanostructures on the separation layer; and a background medium between the plurality of first nanostructures and between the plurality of second nanostructures, wherein each of the plurality of first nanostructures comprises a first layer and a second layer on the first layer, wherein the plurality of first nanostructures comprises: a first-first nanostructure; and a second-first nanostructure that is closer than the first-first nanostructure to a center, in a second direction crossing the first direction, of the light-emitting device, wherein a width of the second layer of the second-first nanostructure in the second direction is smaller than a width of the second layer of the first-first nanostructure in the second direction, and wherein each of the plurality of second nanostructures comprises a single layer and does not include the second layer.

20. A display apparatus comprising: a light-emitting device comprising: a vertical stack structure comprising a first epitaxial structure, a second epitaxial structure on the first epitaxial structure in a first direction, and a third epitaxial structure on the second epitaxial structure in the first direction; a separation layer on the third epitaxial structure in the first direction; a plurality of nanostructures on the separation layer in the first direction; and a background medium between the plurality of nanostructures; and a driving device configured to drive the light-emitting device, wherein each of the plurality of nanostructures comprises a first layer and a second layer on the first layer in the first direction.
